(19) United States
(12) Patent Application Publication
(10) Pub. No.: US 2026/0068703 A1
(43) Pub. Date: Mar. 5, 2026

(54) PACKAGING DEVICES AND METHODS FOR FORMING THE SAME

(71) Applicant: Qorvo US, Inc., Greensboro, NC (US)

(72) Inventors: Deep Chandra Dumka, Richardson, TX (US); Kevin Anderson, Plano, TX (US); Tarak A. Railkar, Carrollton, TX (US)

(21) Appl. No.: 19/319,540

(22) Filed: Sep. 4, 2025

Related U.S. Application Data
(60) Provisional application No. 63/690,943, filed on Sep. 5, 2024.
(60) Provisional application No. 63/733,772, filed on Dec. 13, 2024.

(51) Int. Cl. H01L 23/538; H01L 21/48; H01L 23/00; H01L 23/498; H01L 23/66

(52) U.S. Cl. CPC H01L 23/5385

(57) ABSTRACT

A packaging device is provided. The packaging device includes a die disposed over a laminate, the die comprising a first via structure, and an interposer disposed between the die and the laminate. The interposer includes a second via structure. The packaging device also includes a lid disposed over the interposer and covering the die, a first patterned conductive layer disposed between the die and the interposer, and between the lid and the interposer; and a second patterned conductive layer disposed between the laminate and the interposer. The first patterned conductive layer includes a bonding structure electrically and thermally connected to the first via structure and the second via structure.

### CROSS REFERENCE TO RELATED APPLICATION(S)

The present application claims the benefit of U.S. Provisional Application Number 63/690,943, entitled “NOVEL ON-PACKAGE ELECTROMAGNETIC ABSORBER” and filed on Sep. 5, 2024, and U.S. Provisional Application Number 63/733,772, entitled “NOVEL ON-PACKAGE ELECTROMAGNETIC ABSORBER” and filed on Dec. 13, 2024, which are hereby incorporated by reference in their entireties.

### TECHNICAL FIELD

The present disclosure relates generally to semiconductor manufacturing methodologies and related implementations, and in particular, relates to packaging devices and methods for forming the packaging devices.

### BACKGROUND

Radio frequency (RF) systems are important for modern commercial and defense applications. With ever increasing demand for bandwidth and mobility, RF systems are continuously pushed towards higher frequencies (in microwave to millimeter wave range and even higher) that also requires miniaturization of the RF modules. Packaging of such advanced RF modules becomes highly challenging as conventional packaging approaches significantly limit RF performance and may be incompatible for environmental protection due to size constraints of the RF modules.

Thus, novel packaging devices may be needed that enable maximum exploitation of the RF performance of the dies, e.g., monolithic microwave integrated circuits (MMICs), in the module while also allowing environmental robustness in small form-factor.

### SUMMARY

Some aspects of the present disclosure provide a packaging device. The packaging device includes a die disposed over a laminate, the die including a first via structure, and an interposer disposed between the die and the laminate. The interposer includes a second via structure, and a lid disposed over the interposer and covering the die. The packaging device also includes a first patterned conductive layer disposed between the die and the interposer, and between the lid and the interposer, and a second patterned conductive layer disposed between the laminate and the interposer, wherein the first patterned conductive layer includes a bonding structure electrically and thermally connected to the first via structure and the second via structure.

In some embodiments, the first patterned conductive layer further includes a second bonding structure in contact with the die and the interposer in an area outside the first via structure and the second via structure.

In some embodiments, the second bonding structure is in contact with a third via structure in the interposer.

In some embodiments, the first patterned conductive layer further includes a third bonding structure in contact with the lid and the interposer.

In some embodiments, the third bonding structure is electrically and thermally connected to a fourth via structure in the interposer, the fourth via structure being electrically connected to ground (GND).

In some embodiments, the first patterned conductive layer and the second patterned conductive layer each includes a plurality of metal layers.

In some embodiments, the first patterned conductive layer and the second patterned conductive layer each includes a layer of tin (Sn) between two layers of gold (Au).

In some embodiments, the second patterned conductive layer includes a fourth bonding structure in contact with the third via structure in the interposer and the laminate.

In some embodiments, the second patterned conductive layer includes a fifth bonding structure in contact with the fourth via structure and the laminate.

In some embodiments, the lid includes a fifth via structure extending through a protruding edge; and the first patterned conductive layer includes a sixth bonding structure in contact between the lid and the interposer. The fifth via structure is electrically and thermally connected to the sixth bonding structure.

In some embodiments, the packaging device further includes a seventh bonding structure disposed over the lid and electrically and thermally connected to the fifth via structure.

In some embodiments, the packaging device further includes an eighth bonding structure disposed over and in contact with the lid in an area outside the seventh bonding structure.

In some embodiments, the packaging device further includes a second die in contact with the seventh bonding structure and the eighth bonding structure. The second die includes a sixth via structure being electrically and thermally connected to the seventh bonding structure.

In some embodiments, the packaging device further includes a ninth bonding structure and a tenth bonding structure over the second die. The ninth bonding structure is electrically and thermally connected to the sixth via.

In some embodiments, the die includes a monolithic microwave integrated circuit (MMIC).

In some embodiments, the second die includes an antenna die.

Some aspects of the present disclosure provide a method for preparing a packaging device. The method includes forming a die structure including a first via structure in a die and a first bonding layer over the die. The first bonding layer includes a first bonding pad electrically and thermally connected to the first via structure and a second bonding pad in an area outside the first via structure. The method also includes forming an interposer structure including a second via structure in an interposer and a second bonding layer over the interposer. The second bonding layer includes a third bonding pad electrically and thermally connected to the second via structure. The method further includes bonding the die structure and the interposer structure such that the first bonding pad and the second bonding pad is in contact with the third bonding pad.

In some embodiments, the first bonding layer and the second bonding layer each includes one or more metal layers.

In some embodiments, the forming of the interposer structure further includes forming a third bonding layer on an opposite side of the interposer. The third bonding layer includes a fourth bonding pad electrically and is thermally connected to the second via structure and a fifth bonding pad in an area outside the second via structure.

Some aspects of the present disclosure provide a wireless device with a packaging device. The packaging device includes a die disposed over a laminate. The die includes a first via structure. The packaging device also includes an interposer disposed between the die and the laminate, the interposer having a second via structure. The packaging device also includes a lid disposed over the interposer and covering the die. The packaging device also includes a first patterned conductive layer disposed between the die and the interposer, and between the lid and the interposer. The packaging device further includes a second patterned conductive layer disposed between the laminate and the interposer. The first patterned conductive layer includes a bonding structure electrically connected to the first via structure and the second via structure.

### BRIEF DESCRIPTION OF THE DRAWINGS

Illustrative embodiments of the present disclosure will be described with reference to the accompanying drawings, of which:

FIG. 1A illustrates a cross-sectional view of an example packaging device, according to aspects of the present disclosure.

FIG. 1B shows cross-sectional views of example via structures in the packaging device in FIG. 1A, according to aspects of the present disclosure.

FIG. 2 illustrates a cross-sectional view of another example packaging device, according to aspects of the present disclosure.

FIG. 3 illustrates a flowchart for a method for preparing an example packaging device, according to aspects of the present disclosure.

FIGS. 4A-4F illustrates different parts for preparing a packaging device, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

Embodiments of the present disclosure include packaging devices and methods for manufacturing the packaging devices. The packaging devices are compatible with the scaling of the RF modules and can provide environmental protection and signal transmission of the scaled RF modules. The disclosed packaging devices provide a manufacturable solution to minimize the impact of packaging on the RF performance of the, e.g., MMICs in the RF modules, to reduce the size and weight of the RF systems and to protect the sensitive MMICs from hazardous environmental conditions using a packaging scheme which is also designed for fine leak compliance. Besides, the disclosed packaging devices may allow three-dimensional (3D)-integration of more than one MMIC chips as well as a suitable antenna, which is an integral part of such RF modules.

A packaging device may include conductive structures that are distributed in or between various dies in the assembly. The conductive structures may enable signal transmission and/or heat dissipation in the packaging device without the use of conventional wire bonding. The conductive structures allow the dies to be integrated in a compact manner such that the RF loss is reduced and the performance of the RF module is not degraded at high frequency (which can be caused by wire bonding due to the undesirably long length of the wires). Specifically, the conductive structures may include via structures and bonding structures. A via structure may extend partially or fully in a die of the packaging device and is configured to transmit a signal (e.g., DC, RF, or both) with much shorter length compared to a wire or provide an efficient path for heat dissipation. A bonding structure may electrically and/or thermally connect different dies or different via structures. The size of a packaging device can be reduced, and signals and/or heat can be transmitted more efficiently in the packaging device without compromising RF performance. In some embodiments, conductive structures allow more parts to be stacked and coupled vertically, further improving the level of integration.

It should be noted that, the structures shown in the figures of the present disclosure are for illustrative purposes only, and are not meant to scale or indicate the actual ratio, shape, dimension, or the like, in a product. For example, the via structures shown as extending through a corresponding layer may or may not extend through the layer. In various embodiments, the via structure may partially extend in the layer or fully extend through the layer, depending on the design and the description.

As used herein, the term “electrically connect to” or the like may refer to two components or parts are linked in a way that electrical current or signals can flow between them. The term “thermally connect to” or the like may refer to that heat can transfer between the two components.

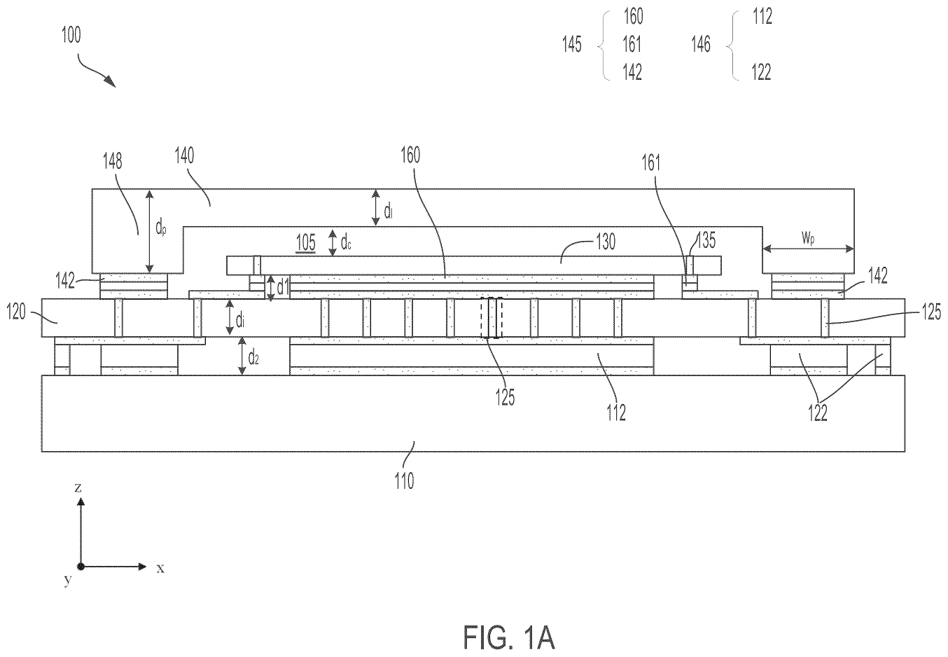

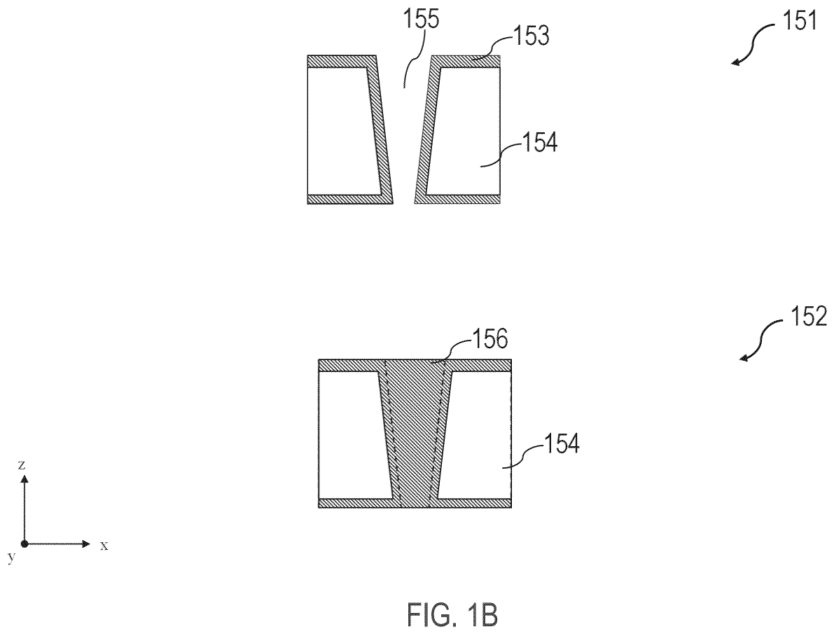

FIG. 1 shows a cross-sectional view of a packaging device 100. Packaging device 100 may include a laminate 110, an interposer 120, a die 130, and a lid 140. The die 130 may be disposed atop, or attached to, the interposer 120, and may be electrically and/or thermally connected to the interposer 120. The interposer 120 be disposed atop, or attached to, the laminate 110, and may be electrically and/or thermally connected to the laminate 110. In some embodiments, the die 130 is electrically and/or thermally connected to the laminate 110.

The die 130 may include a suitable functional die with a first surface facing the laminate 110 and a second surface facing away from the laminate 110. The die 130 may include various electronic devices/modules, e.g., transistor, capacitors, resistors, etc., disposed on or near the second surface, an electrical interface and a thermal interface on the first surface, and interconnect structures (e.g., vias, routings, DC/RF connections, ground contacts, etc.) connecting the electronic devices and the interfaces. The interconnect structures in the die 130 may also function as thermal paths. For ease of illustration, the second surface is referred to an active side, and the first surface is referred to as a non-active side or backside. As an example of the interconnect structures, the die 130 may include one or more via structures 135 electrically and thermally connected to one or more via structures 125 in the interposer 120. In one or more embodiments, the die 130 may include a radio frequency monolithic microwave integrated circuit (MMIC). For example, the MMIC may be configured to operate in a range of frequency between 50 GHz and 150 GHz, between 70 GHz and 130 GHz, between 90 GHz and 110 GHz, or any frequence ranges there between.

The interposer 120 may provide support, and electrical and thermal connections for the die 130. The interposer 120 may include a suitable substrate material such as silicon carbide (SiC), gallium arsenide (GaAs), silicon (Si), aluminum nitride (AlN), diamond, glass, quartz, germanium (Ge), and/or the like. The interposer 120 may have a first face facing the laminate 110 and a second face facing away from the laminate 110. The interposer 120 includes an electrical interface and a thermal interface, on the second surface, that are compatible with the electrical and thermal interfaces of the die 130. In some embodiments, signals (e.g., DC, RF, etc.) can be transmitted between the interposer 120 and the die 130, and heat can be dissipated from the die 130 to the interposer 120.

A via structure 125 or 135, may be vertical vias across part or the entirety of the thickness of the die 130 or the interposer 120, respectively. In some embodiments, the via structures 125 and/or 135 are also referred to as “hot vias” intended to provide DC bias and/or transfer RF signals. In some embodiments, the via structures 125 and/or 135 that electrically connect the die 130 to the lid 140 (“GND”) are referred to as “ground vias.” As shown FIG. 1A, in some embodiments, via structure 125 and via structure 135 may be electrically and/or thermally connected through electrically and/or thermally conductive structures for the purposes of signal transmission and/or heat dissipation.

As further illustrated in FIG. 1, lid 140 (also referred to herein as a lid, a cover, or a cover member) may be attached to the interposer 120. Lid 140 may have a suitable material and thickness to protect the die 130 from environmental contamination. Lid 140 may include a horizontal portion and one or more protruding edges 148 in contact with the horizonal portion. In some embodiments, the thickness dl of the horizontal portion of the lid 140 is between about 100 μm and about 400 μm. In some embodiments, the lid 140 may include a suitable material such as silicon carbide (SiC), silicon (Si), gallium arsenide (GaAs), aluminum nitride (AlN), glass, and/or the like. In one or more embodiments, the one or more protruding edges 148 are attached to the interposer 120, as shown in FIG. 1, such that the attachment forms a cavity 105 that surrounds the die 130 therewithin. A dimension d_{c} of the cavity 105 in the z-direction is sufficiently large to allow die 130 and bonding structures (e.g., 160, 161) to be properly disposed and function, but is significantly reduced compared to a conventional packaging device that employs bonding wires to connect the die with the interposer. In some embodiments, d_{c} is between about 75 μm and about 100 μm. A width wₚ of protruding edge 148 in the x-y plane is between about 50 μm and about 200 μm, and a thickness dₚ of protruding edge 148 in the z-direction is between about 250 μm and about 500 μm, such as 300 μm. It should also be noted that, although a single die 130 is shown as an example in this disclosure, a reasonable number (e.g., equal to or greater than two) of dies, as permitted by the coverage of lid 140 as well as operational constraints amongst the dies, can be disposed on the interposer 120. In some embodiments, a thickness dᵢ of the interposer 120 is between about 50 μm and about 300 μm.

Packaging device 100 may include a patterned conductive layer 145 disposed between the die 130 and the interposer 120, and between the lid 140 and the interposer 120. The patterned conductive layer 145 may facilitate the transmission of signals (e.g., DC, RF, etc.) and/or heat dissipation between the electrical interfaces of die 130 and the interposer 120, and between electrical, thermal and/or mechanical interfaces of the lid 140 and the interposer 120. Patterned conductive layer 145 may also facilitate the sealing of the die 130 to reduce/prevent contamination. Specifically, the patterned conductive layer 145 may attach/bond the die 130 onto the interposer 120, and attach/bond the lid 140 onto the interposer 120. Patterned conductive layer 145 may include a bonding structure 160 and a bonding structure 161 disposed between the die 130 and the interposer 120. Bonding structures 160 and 161 may both be in contact with the die 130 and the interposer 120. In some embodiments, a thickness d1 of patterned conductive layer 145 is between about 35 μm and about 115 μm.

Bonding structure 160 may attach the die 130 onto the interposer 120, and may help with heat dissipation from die 130. In an example, bonding structure 160 is not electrically connected to via structures 125 in the interposer 120, and may be disposed in an area outside via structures 135. In some embodiments, bonding structure 160 may be in contact with one or more via structures 125 in the interposer 120 for dissipating heat from the die 130 to the laminate 110.

Bonding structure 161 may facilitate the electrical connection between the die 130 and the interposer 120, and may facilitate heat dissipation from the die 130 to the interposer 120. In some embodiments, a via structure 135 is electrically connected to a via structure 125 through a bonding structure 161.

Patterned conductive layer 145 may further include a bonding structure 142 disposed between protruding edge 148 of the lid 140 and the interposer 120. Bonding structure 142 may be in contact with protruding edge 148 (e.g., lid 140) and interposer 120, and may be electrically and/or thermally connected to (and/or in contact with) a via structure 125 in the interposer 120. In some embodiments, lid 140 is electrically connected to a via structure 125, and may be grounded through the via structure 125. In some embodiments, bonding structure 142 may be referred to as a “seal ring”that prevents environmental contaminants from leaking into the cavity 105.

As shown in FIG. 1, bonding structures 160, 161, and 142 (e.g., of the patterned conductive layer 145) may have the same/even thickness along the z-direction, and may include a single layer or metal or multiple layers of metals. Depending on factors such as the design and/or the function(s), bonding structures 160, 161, and 142 may have various shapes and patterns. In some embodiments, bonding structures 160, 161, and 142 are formed in the same fabrication process(es). In some embodiments, the patterned conductive layer 145 (or each of bonding structures 160, 161, and 142) includes a single metal layer such as gold (Au), copper (Cu), tin (Sn), aluminum (Al), or the like. In some embodiments, the patterned conductive layer 145 includes multiple metal layers such as Au-Sn, stacked in the z-direction. For example, the patterned conductive layer 145 may include a gold-tin-gold configuration, with the gold layer being between about 5 μm and about 30 μm, and the tin layer being between about 1 μm and about 25 μm. In some embodiments, the metal layer (e.g., gold layer) that is in contact with die 130 (and/or via structure 135), the interposer 120 (and/or via structure 125) may also be referred to as backside electro-thermal interface (BETI) pads. In some embodiments, the metal layer (e.g., tin layer) that is between two BETI pads may also be referred to as BETI/seal ring compatible pad. Depending on the design, the BETI pads and/or the BETI/seal ring compatible pads can have any suitable shape and/or length to facilitate the electrical and/or thermal conduction.

Packaging structure 100 may further include a patterned conductive layer 146 disposed between the interposer 120 and the laminate 110. The patterned conductive layer 146 may attach/bond interposer 120 onto the laminate 110, and may facilitate the transmission of signals (e.g., DC, RF, etc.) and/or heat dissipation between the laminate 110 and the electrical and thermal interfaces of the interposer 120, and between the laminate 110 and the electrical and thermal interfaces of the lid 140. Patterned conductive layer 146 may include bonding structures 112 and 122 in contact with the interposer 120 and the laminate 110. Bonding structure 112 may be in contact with a plurality of via structures 125 to help dissipating heat from the die 130 to the laminate 110. Bonding structure 122 may be electrically and/or thermally connected to the via structure 125 that is electrically and/or thermally connected to the via structure 135. Bonding structure 122 may also be electrically and/or thermally connected to the via structure 125 that is electrically and/or thermally connected to the lid 140 through bonding structure 142. Bonding structure 122 may be in contact with the interposer 120 and the laminate 110. In some embodiments, a thickness d2 of patterned conductive layer 146 is between about 35 μm and about 115 μm.

As shown in FIG. 1, bonding structures 112 and 122 (e.g., of the patterned conductive layer 146) may have the same/even thickness along the z-direction, and may include a single layer or metal or multiple layers of metals. In some embodiments, bonding structures 122 and 112 are formed in the same fabrication process(es). In some embodiments, the patterned conductive layer 146 (or each of bonding structures 122 and 112) includes a single metal layer such as gold (Au), copper (Cu), tin (Sn), aluminum (Al), or the like. In some embodiments, the patterned conductive layer 146 includes multiple layers stacked in the z-direction. For example, the patterned conductive layer 146 may include a gold-tin-gold configuration, with the gold layer being between about 5 μm and about 30 μm, and the tin layer being between about 1 μm and about 25 μm. In some embodiments, the metal layer (e.g., gold layer) that is in contact with the interposer 120 (and/or via structure 125) may also be referred to as BETI pads.

The laminate 110 may include an organic composite and a plurality of wirings that are electrically connected to an external circuit, in accordance with one embodiment. In various embodiments, patterned conductive layers 145 and/or 146 may or may not include soldering balls as bonding structures 161 and/or 122. In some embodiments, patterned conductive layers 145 and/or 146 may include a land grid array (LGA).

FIG. 1B shows different configurations 151 and 152 of a via structure 125, according to some embodiments. Via structure 125, in both configurations 151 and 152, may not only be used for electrical connection, but also serve as a means for thermal conduction. In configuration 151, the via structure 125 may include a conductive layer 153 disposed on a sidewall of a through hole that extends in the interposer 120, and an air cavity 155 surrounded by the conductive layer 153. The conductive layer 153 may be in contact with the material 154 of the interposer 120. For example, material 154 may include an insulating material such as a dielectric material. In configuration 152, the via structure 125 may include a conductive layer 156 that fills a through hole that extends in the interposer 120, e.g., without any air cavity. In both configurations, the conductive layers 153 and 156 may each include one or more layers of metals such as, gold (Au), silver (Ag), copper (Cu), tin (Sn), aluminum (Al), or any combination. Depending on the fabrication and/or material, the area/width of the cross-section of configurations 151 and 152 may vary or stay constant. For example, the area/width may increase/decrease in the z-direction. In various embodiments, the via structures 135 may have configurations 151 and/or 152.

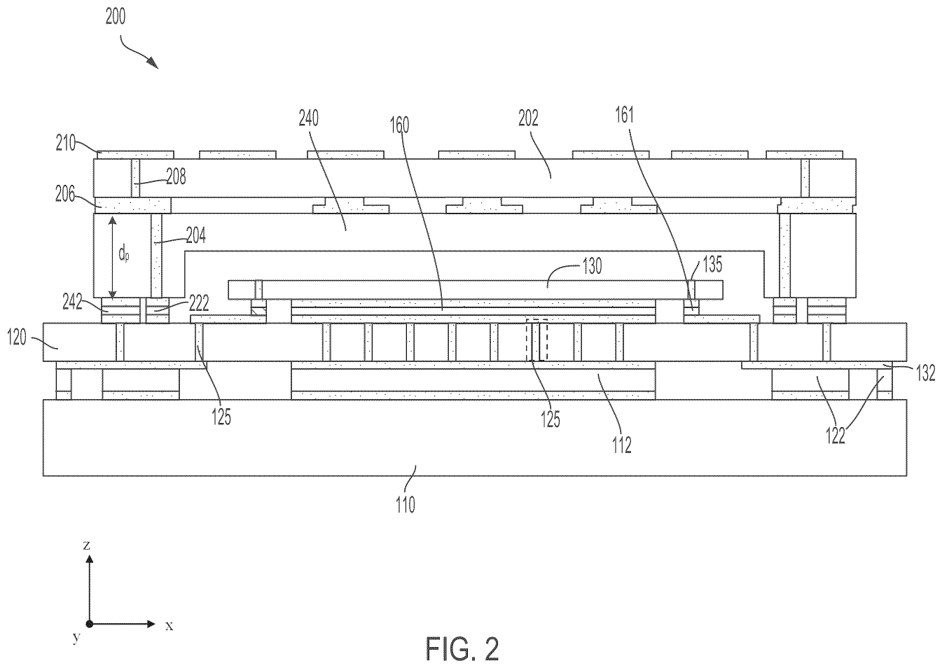

FIG. 2 shows a cross-sectional view of another packaging device 200. Different from packaging device 100, packaging device 200 may include a lid 240 that is configured to electrically and/or thermally connected to another die 202 mounted on lid 240. To facilitate electrical connection, the patterned conductive layer 245 disposed between the lid 240 and the interposer 120 includes a bonding structure 222 and a bonding structure 242. In some embodiments, bonding structure 242 may be referred to as a “seal ring” that prevents environmental contaminants from leaking into the cavity 105. In some embodiments, bonding structures 222 and 242 have similar or same materials and configurations as bonding structures 106 and 161, and the detailed description is not repeated herein. For ease of illustration, a first surface of lid 240 is facing the laminate 110, and a second surface of lid 240 is facing away from the laminate 110. The description of similar or the same elements in packaging device 200 are not repeated herein.

As shown in FIG. 2, lid 240 includes one or more via structures 204 extending in (e.g., or through) protruding edges 148. The via structure 204 may be electrically and/or thermally connected to (and/or in contact with) bonding structure 222, which is further electrically and/or thermally connected to a via structure 125 (and the interposer 120). The via structure 204 may also be electrically connected to (and/or in contact with) a bonding structure 206 disposed on the second surface of lid 240. Bonding structure 242 may be separated from bonding structure 222, and may be electrically and/or thermally connected to the lid 240 and the interposer 120. For example, bonding structure 242 is electrically and/or thermally connected to via structure 125. In some embodiments, via structure 204 can have configurations 151 and/or 152.

The lid 240 may include an electrical interface and a thermal interface that include one or more bonding structures 206 disposed on the second surface of lid 240. The electrical and thermal interfaces of the lid 240 may be compatible with the electrical and thermal interfaces of any die 202 that is integrated into the packaging device 200 by stacking over the lid 240. In some embodiments, one or more bonding structures 206 are electrically and/or thermally connected to (and/or in contact with) corresponding via structures 204 to facilitate electrical and/or thermal connection. In some embodiments, one or more bonding structures 206 are in contact with the lid 240 and another die 202 to facilitate heat dissipation and/or signal transmission. For ease of description, the bonding structures 206 are in contact with a first surface of the other die 202. In some embodiments, bonding structures 206 are referred to as BETI pads.

Bonding structures 206 may include a single layer of conductive layer or multiple layers of conductive layers. In some embodiments, bonding structures 206 includes a single metal layer such as gold (Au), copper (Cu), tin (Sn), aluminum (Al), or the like. In some embodiments, the bonding structure 206 includes multiple metal layers such as Au-Sn stacked in the z-direction. In some embodiments, bonding structures 206 are disposed on a dielectric layer such as silicon oxide, silicon nitride, silicon oxynitride, or any combination.

The other die 202 may include any suitable functional die that may or may not communicate with die 130. The other die 202 may include one or more via structures 208 that are electrically and/or thermally connected to (and/or in contact with) bonding structures 206. In some embodiments, via structures 208 can have configurations 151 and/or 152. The electrical and/or thermal conduction between the other die 202 and the die 130 can be facilitated by via structures 208, 204, 125, and bonding structures 206, 222. As an example, the other die 202 is an antenna die that can convert between electrical signals and electromagnetic waves. In various embodiments, the die 130 may modulate and/or amplify RF signals, and the antenna die may transmit/radiates the RF signal; and/or the antenna die may receive RF signals, and the die 130 processes the received RF signals. In some embodiments, a thickness da of the antenna die is between about 50 μm and about 300 μm.

In some embodiments, depending on the design, packaging device 200 includes one or more bonding structures 210 disposed on a second surface of the other die 202 for electrical and/or thermal transmission with a third die (not shown), if applicable. The third die may include any suitable functional die that communicates with die 130 and/or the other die 202, and may include one or more via structures that are electrically and/or thermally connected to (and/or in contact with) bonding structures 210. One or more bonding structures 210 are each electrically and/or thermally connected to (and/or in contact with) a corresponding via structure 208, and one or more bonding structures 210 are thermally connected to (e.g., in contact with) the other die 202 and the third die. In some embodiments, the bonding structure 210 includes a single metal layer such as gold (Au), copper (Cu), tin (Sn), aluminum (Al), or the like. In some embodiments, the bonding structure 210 includes multiple metal layers such as Au-Sn stacked in the z-direction.

It should be noted that, although not shown, any reasonable number of dies can be stacked over the lid 240 using bonding structures (e.g., 142, 122, 206, etc.) and via structures (e.g., 125, 135, 204, 208, etc.) similar to those described in the present disclosure. the functionalities and the number of dies that can be stacked should not be limited to the embodiments of the present disclosure.

As shown in the examples in FIGS. 1A, 1B, and 2, the packaging devices of the present disclosure (100 and 200) may include electrical and thermal interfaces between different components to facilitate electrical connections and heat dissipation. The electrical and thermal interfaces may include various bonding structures (e.g., 112, 122 142, 160, 161, 222, 242, 206, 210, etc.) and via structures (e.g., 125, 135, 204, 208, etc.) of desirably high electrical conductivity and/or thermal conductivity. Specifically, the via structures, with configurations 151 and/or 152, may not serve only as means for electrical connection but also an effective way of heat dissipation. Compared to an existing packaging devices based on wire bonding, the vias significantly shortens the transmission line between dies, and reduces RF losses. Meanwhile, heat dissipation amongst dies are improved by the use of vias and bonding structures.

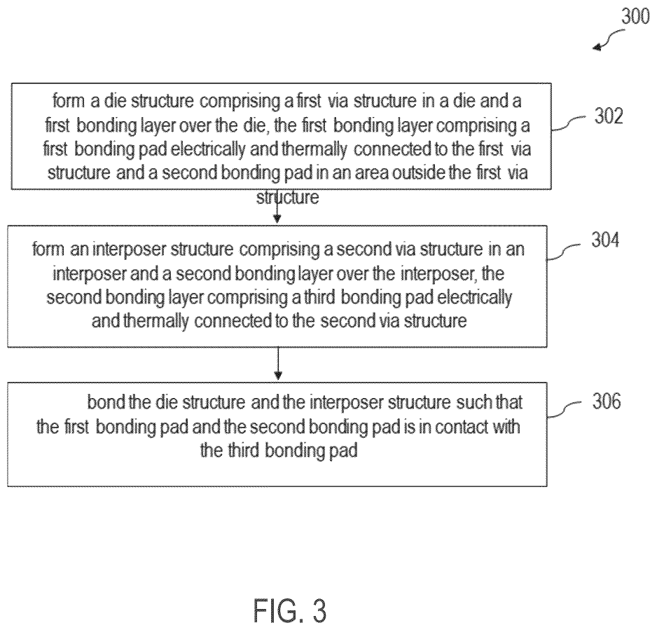

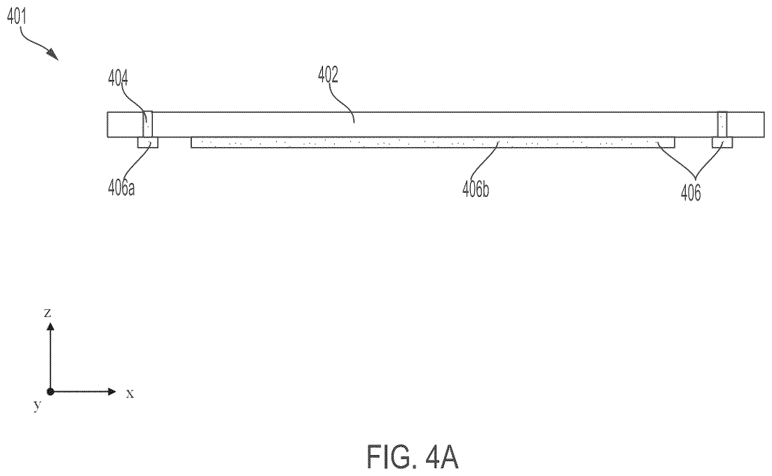

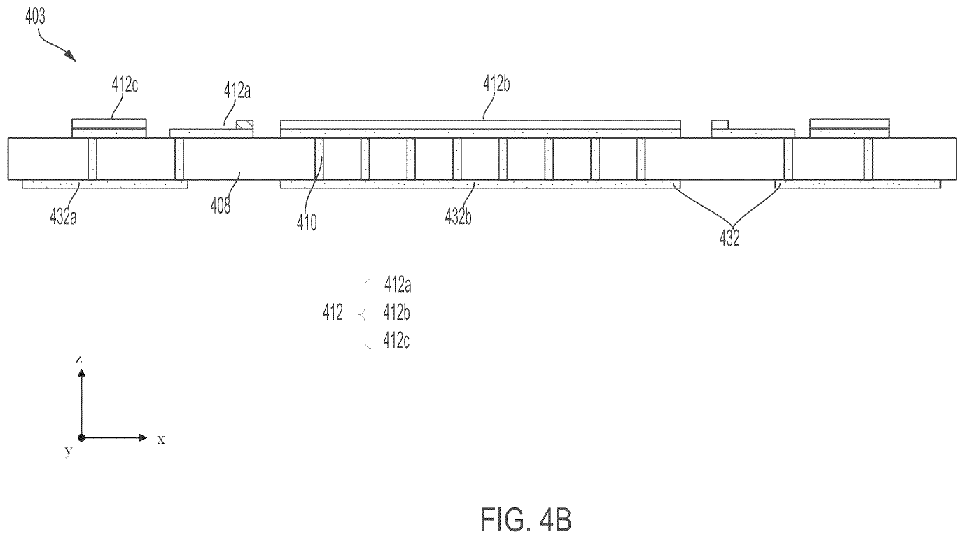

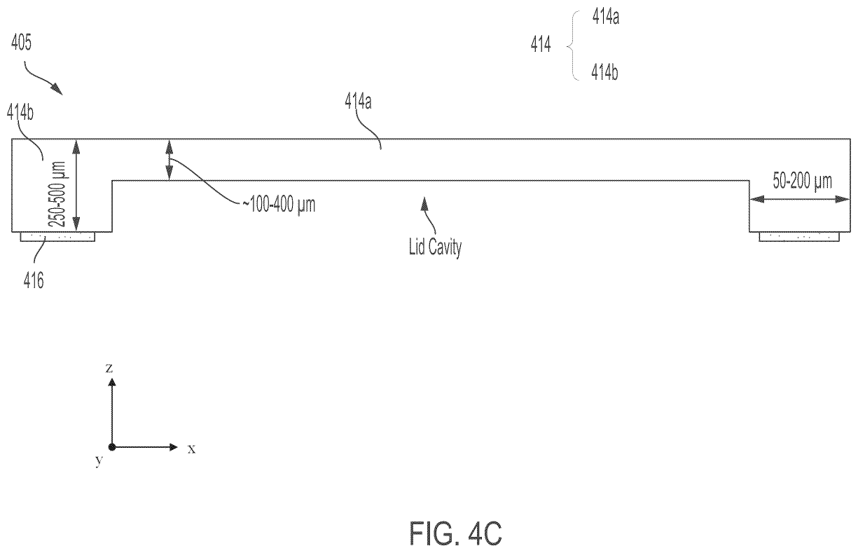

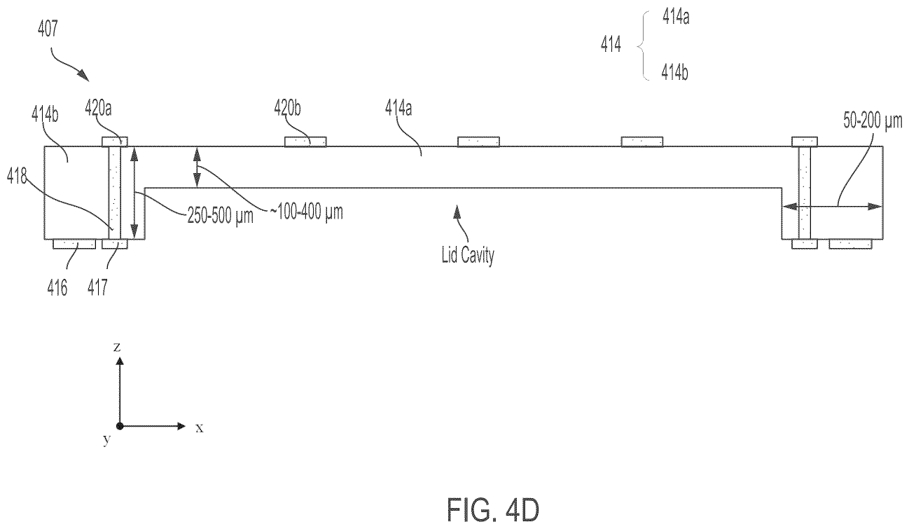

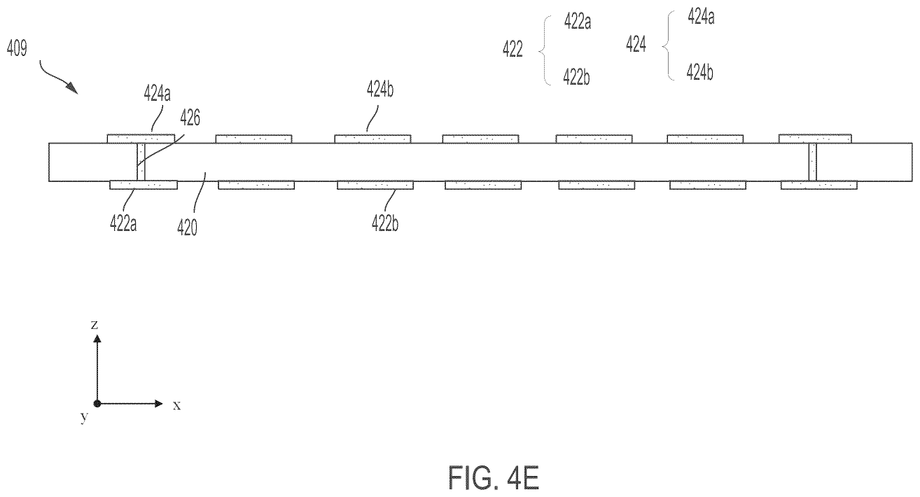

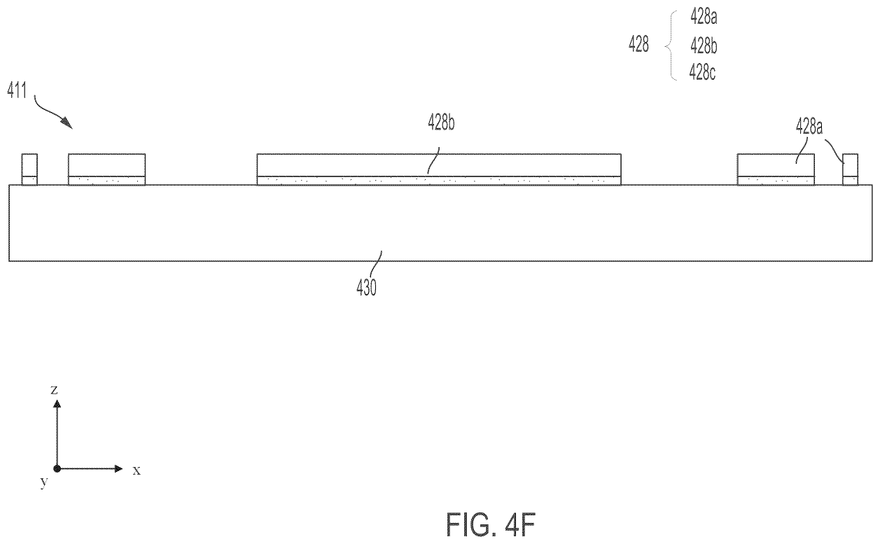

FIG. 3 shows a flowchart of a method 300 for forming a packaging device of the present disclosure, according to embodiments of the present disclosure. The packaging device may be an example of packaging devices 100 and 200. Method 300 is merely an example, and is not intended to limit the present disclosure beyond what is explicitly recited in the claims. Additional operations can be provided before, during, and after the method 300, and some operations described can be replaced, eliminated, or moved around for additional embodiments of method 300. Method 300 will be described in more detail below. Specifically, FIGS. 4A-4F illustrate structures of different components of a packaging device. FIG. 3 will be described in view of FIGS. 4A-4F, 1A, and 2.

At step 302, a die structure is formed. The die structure includes a first via structure in a die and a first bonding layer over the die. The first bonding layer includes a first bonding pad electrically and thermally connected to the first via structure and a second bonding pad in an area outside the first via structure. FIG. 4A shows a corresponding structure.

As shown in FIG. 4A, a die structure 401 is formed. The die structure 401 may include a die 402, a via structure 404 extending in the die 402, and a bonding layer 406 disposed on the die 402. In some embodiments, the die 402 includes a RF MMIC die. The bonding layer 406 may be disposed on an inactive side (or backside) of the die 402, and may include a bonding pad 406a and a bonding pad 406b. The bonding pad 406a may be electrically and/or thermally connected to the via structure 404, and the bonding pad 406b may be disposed in an area outside the via structure 404. In some embodiments, the bonding layer 406 includes one or more metal layers such as gold (Au), and has a thickness between about 5 μm and about 20 μm. In some embodiments, the bonding layer 406 is also referred to as BETI pads.

At step 304, an interposer structure is formed. The interposer structure includes a second via structure in an interposer and a second bonding layers disposed on the interposer. The second bonding layer may include a third bonding pad electrically and thermally connected to the second via structure. FIG. 4B shows a corresponding structure.

As shown in FIG. 4B, an interposer structure 403 is formed. The interposer structure 403 may include a via structure 410 in an interposer 408, a bonding layer 412 over a first surface of the interposer 408, and a bonding layer 432 over a second surface of the interposer 408. The bonding layer 412 may include bonding pads 412a, 412b, and 412c. The bonding layer 432 may include bonding pads 432a and 432b. Bonding pad 412b may be electrically and/or thermally connected to bonding pad 432b through via structures 410. Bonding pads 412a and 412c may be electrically and/or thermally connected to bonding pad 432a through the via structure 410. In some embodiments, bonding pad 412c is configured to attach a lid. In some embodiments, bonding pad 412a is configured to attach bonding pad 406a. In some embodiments, the bonding layers 412 and/or 432 include a single metal layer or multiple metal layers such as gold, or tin over gold (Sn-Au) or a combination of copper (Cu), nickel (Ni), and/or gold (Au). In some embodiments, bonding pads 412a, 412b, 412c, 432a, and 432b are also referred to as BETI pads.

At step 306, the die structure and the interposer structure are bonded together such that the first bonding pad and the second bonding pad are in contact with the third bonding pad.

Referring back to FIG. 1, die structure 401 and interposer structure 403 are bonded together, e.g., using a suitable bonding method such as metal-to-metal bonding. Bonding pad 406a is in contact with bonding pad 412a (to form the bonding structure 161), and bonding pad 406b is in contact with bonding pad 412b (to form the bonding structure 160).

In some embodiments, method 300 also includes forming a lid structure and bonding the lid structure atop the interposer 408 for covering the die 402. FIGS. 4C and 4D show two configurations of lid structures.

In some embodiments, as shown in FIG. 4C, lid structure 405 includes a lid 414 that includes a horizontal portion 414a extending in the x-y plane and a protruding portion 414b extending in the z-direction. The lid structure 405 may also include a bonding layer 416 (e.g., a bonding pad) disposed on the surface of the protruding portion 417b that is facing away from the horizontal portion 414a. In some embodiments, a thickness of the horizontal portion 414a is between about 100 μm and about 400 μm in the z-direction, and a thickness of the protruding portion 414b is between about 250 μm and about 500 μm in the z-direction.

In some embodiments, as shown in FIG. 4D, compared to lid structure 405, lid structure 407 further includes a via structure 418 extending in the protruding portion 414b. Lid structure 407 may also include a bonding layer 420 disposed on the lid 414, on the opposite side of the bonding layer 416, and a bonding layer 417 (e.g., bonding pad) disposed on the same surface as bonding layer 416. Bonding layer 417 may be electrically and/or thermally connected to via structure 418. The bonding layer 420 may include a bonding pad 420a electrically and/or thermally connected to the via structure 418 and one or more bonding pads 420b not coupled to via structure 418. In some embodiments, bonding layers 416 and/or 417 may be bonded to bonding pad 412c and form a lid seal ring.

In some embodiments, a second die structure 409 is formed. FIG. 4E shows a corresponding structure. The second die structure 409 may include a die 420, a via structure 426 extending in the die 420, a bonding layer 422 disposed on the first surface of die 420, and a bonding layer 424 disposed on the second surface of die 420. In some embodiments, the die 420 includes any suitable functional die such as an antenna die. The bonding layer 422 may include a bonding pad 422a electrically and/or thermally connected to the via structure 426, and a bonding pad 422b disposed in an area outside the via structure 426. The bonding layer 424 may include a bonding pad 424a electrically and/or thermally connected to the via structure 426, and a bonding pad 424b disposed in an area outside the via structure 426. In some embodiments, the bonding layers 422 and 424 each includes one or more metal layers such as gold (Au), and has a thickness between about 5 μm and about 20 μm.

In some embodiments, a laminate structure 411 is formed. FIG. 4F shows a corresponding structure. The laminate structure 411 may include a multi-layer laminate 430 with a bonding layer 428 disposed on a surface. The bonding layer 428 may include a bonding pad 428a for electrically and/or thermally connecting to bonding pad 432a, and a bonding pad 428b for electrically and/or thermally connecting to bonding pad 432b. In some embodiments, the bonding layer 428 includes a multi-layer structure such as a first metal layer in contact with the laminate 430 and a soldering layer over the first metal layer. The first metal layer may include gold (Au), and the soldering layer may include tin (Sn) or a soldering layer of lead (Pb) and tin (Sn) or the like. In some embodiments, the soldering layer has a thickness of between about 25 μm and about 75 μm in the z-direction. In some embodiments, bonding pad 428a includes a printed solder feature.

In some embodiments, the interposer structure 403, bonded with the die structure 401, is bonded with the laminate structure 411 such that bonding pad 432a is bonded with bonding pad 428a to form the bonding structure 122, and bonding pad 432b is bonded with bonding pad 428b to form the bonding structure 112. In some embodiments, the bonding process includes a metal-to-metal bonding process with heat and pressure.

To form a packaging device similar to packaging device 100, the lid structure 405 may be bonded with the interposer structure 403 such that the bonding layer 416 is in contact with the bonding pad 412c. The bonded 416 and 412c may form the bonding structure 142. In some embodiments, the bonding process includes a metal-to-metal bonding process with heat and pressure.

To form a packaging device similar to packaging device 200, the lid structure 407 may be bonded with the interposer structure 403 such that the bonding layer 416 is in contact with the bonding pad 412c. The bonded 416 and 412c may form the bonding structure 142. Also, the second die structure 409 is bonded with the lid structure 407 such that the bonding pad 422a is in contact with the bonding pad 420a, and the bonding pad 422b is in contact with the bonding pad 420b, to form the bonding structures 206. In some embodiments, the bonding process includes a metal-to-metal bonding process with heat and pressure.

In various embodiments, the formation of structures 401, 403, 405, 407, 409, and 411 may include photolithography, dry etch, wet etch, e-beam evaporation, electro-plating, electro-less plating, annealing, atomic layer deposition (ALD), chemical vapor deposition (CVD), physical vapor deposition (PVD), plasma-enhanced chemical vapor deposition (PECVD), molecular beam epitaxy (MBE), metal-organic chemical vapor deposition (MOCVD), chemical mechanical polishing (CMP), and/or any suitable combination.

It should be noted that, the components shown in FIGS. 4A-4F may be formed in any suitable order, and may be formed separately/independently. The processes and orders to form these components are not limited by the embodiments of the present disclosure.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A packaging device comprising:
a die disposed over a laminate, the die comprising a first via structure;
an interposer disposed between the die and the laminate, the interposer comprising a second via structure;
a lid disposed over the interposer and covering the die;
a first patterned conductive layer disposed between the die and the interposer, and between the lid and the interposer; and
a second patterned conductive layer disposed between the laminate and the interposer, wherein the first patterned conductive layer comprises a bonding structure electrically and thermally connected to the first via structure and the second via structure.

2. The packaging device of claim 1, wherein the first patterned conductive layer further comprises a second bonding structure in contact with the die and the interposer in an area outside the first via structure and the second via structure.

3. The packaging device of claim 2, wherein the second bonding structure is in contact with a third via structure in the interposer.

4. The packaging device of claim 1, wherein the first patterned conductive layer further comprises a third bonding structure in contact with the lid and the interposer.

5. The packaging device of claim 4, wherein the third bonding structure is electrically and thermally connected to a fourth via structure in the interposer, the fourth via structure being electrically connected to ground (GND).

6. The packaging device of claim 1, wherein the first patterned conductive layer and the second patterned conductive layer each comprises a plurality of metal layers.

7. The packaging device of claim 4, wherein the first patterned conductive layer and the second patterned conductive layer each comprises a layer of tin (Sn) between two layers of gold (Au).

8. The packaging device of claim 3, wherein the second patterned conductive layer comprises a fourth bonding structure in contact with the third via structure in the interposer and the laminate.

9. The packaging device of claim 5, wherein the second patterned conductive layer comprises a fifth bonding structure in contact with the fourth via structure and the laminate.

10. The packaging device of claim 1, wherein:
the lid comprises a fifth via structure extending through a protruding edge; and
the first patterned conductive layer comprises a sixth bonding structure in contact between the lid and the interposer, the fifth via structure being electrically and thermally connected to the sixth bonding structure.

11. The packaging device of claim 10, further comprising a seventh bonding structure disposed over the lid and electrically and thermally connected to the fifth via structure.

12. The packaging device of claim 11, further comprising an eighth bonding structure disposed over and in contact with the lid in an area outside the seventh bonding structure.

13. The packaging device of claim 12, further comprising a second die in contact with the seventh bonding structure and the eighth bonding structure, wherein the second die comprises a sixth via structure being electrically and thermally connected to the seventh bonding structure.

14. The packaging device of claim 13, further comprising a ninth bonding structure and a tenth bonding structure over the second die, wherein the ninth bonding structure is electrically and thermally connected to the sixth via.

15. The packaging device of claim 1, wherein the die comprises a monolithic microwave integrated circuit (MMIC).

16. The packaging device of claim 13, wherein the second die comprises an antenna die.

17. A method for preparing a packaging device, comprising:
forming a die structure comprising a first via structure in a die and a first bonding layer over the die, the first bonding layer comprising a first bonding pad electrically and thermally connected to the first via structure and a second bonding pad in an area outside the first via structure;
forming an interposer structure comprising a second via structure in an interposer and a second bonding layer over the interposer, the second bonding layer comprising a third bonding pad electrically and thermally connected to the second via structure; and
bonding the die structure and the interposer structure such that the first bonding pad and the second bonding pad is in contact with the third bonding pad.

18. The method of claim 17, wherein the first bonding layer and the second bonding layer each comprises one or more metal layers.

19. The method of claim 17, wherein the forming of the interposer structure further comprises forming a third bonding layer on an opposite side of the interposer, the third bonding layer comprising a fourth bonding pad electrically and thermally connected to the second via structure and a fifth bonding pad in an area outside the second via structure.

20. A wireless device comprising a packaging device, the packaging device comprising:
a die disposed over a laminate, the die comprising a first via structure;
an interposer disposed between the die and the laminate, the interposer comprising a second via structure;
a lid disposed over the interposer and covering the die;
a first patterned conductive layer disposed between the die and the interposer, and between the lid and the interposer; and
a second patterned conductive layer disposed between the laminate and the interposer, wherein the first patterned conductive layer comprises a bonding structure electrically connected to the first via structure and the second via structure.
